(19) United States
(12) Patent Application Publication
(10) Pub. No.: US 2026/0363051 A1
(43) Pub. Date: Nov. 12, 2026

(54) APPARATUS INCLUDING MEMORY CELL CAPACITOR AND CONTACT PLUG STRUCTURE

(71) Applicant: Micron Technology, Inc., Boise, ID (US)

(72) Inventors: Akira Kaneko, Hiroshima (JP); Naokazu Murata, Higashihiroshima-shi (JP); Keisuke Shimada, Higashihiroshima-shi (JP)

(73) Assignee: Micron Technology, Inc., Boise, ID (US)

(21) Appl. No.: 19/648,852

(22) Filed: Apr. 15, 2026

Related U.S. Application Data
(60) Provisional application No. 63/801,515, filed on May 7, 2025.

(51) Int. Cl. H10W 20/42; H10B 12/00; H10W 20/41; H10W 20/43; H10W 20/44; H10W 20/48

(52) U.S. Cl. CPC H10W 20/422; H10B 12/482; H10W 20/43; H10W 20/435; H10W 20/438; H10W 20/4437; H10W 20/4451; H10W 20/48; H10B 12/0335; H10B 12/315; H10B 12/318; H10B 12/34

(57) ABSTRACT

Some embodiments of the disclosure provide an apparatus comprising memory cell capacitors, contact plugs, and insulating members. The contact plugs couple the associated memory cell capacitors to active regions formed in a semiconductor substrate. The insulating members isolate neighboring contact plugs from each other. The contact plugs each include a lower conductive plug (including polysilicon and cobalt/cobalt silicide, for example) and an upper conductive plug (including titanium/titanium nitride and tungsten, for example). The upper conductive plug has a bottom part located higher than a bottom part of the insulating member above the semiconductor substrate. The memory cell capacitors are directly coupled to the upper conductive plugs of the associated contact plugs, without any intermediate conductive elements, such as a redistribution layer.

### CROSS REFERENCE TO RELATED APPLICATIONS

This application claims the benefit under 35 U.S.C. § 119 of the earlier filing date of U.S. Provisional Application Serial No. 63/801,515 filed May 7, 2025. The aforementioned application is incorporated herein by reference, in its entirety, for any purpose.

### BACKGROUND

High data reliability, high speed of memory access, low power consumption, and reduced chip size are some features that are demanded from semiconductor memory devices, such as a dynamic random-access memory (DRAM). A memory device may include a plurality of memory cells located at intersections of word lines arranged in rows and bit lines arranged in columns. Each memory cell may include a capacitor for data storage and a transistor for accessing the capacitor. A memory cell capacitor may be coupled to either source or drain of an associated memory cell transistor formed in active regions of a semiconductor substrate, via a cell contact and a redistribution layer. A cell contact may be coupled at one end to either the source or drain region and at another end to a redistribution layer. The redistribution layer may then be coupled to the associated memory cell capacitor. The cell contact and the redistribution layer may thus serve to couple the cell capacitor to one of the source/drain regions in the semiconductor substrate. A bit line may be coupled to the other source/drain region.

### BRIEF DESCRIPTION OF THE DRAWINGS

FIGS. 1A and 1B depict an example configuration of at least part of a memory device in a plan view and a cross-sectional view, respectively, according to some embodiments of the disclosure.

FIGS. 2A-2B-7A-7B depict example processes of forming at least part of a memory device in a plan view and a cross-sectional view according to some embodiments of the disclosure.

FIGS. 8A and 8B depict an example configuration of at least part of a memory device in a plan view and a cross-sectional view, respectively, according to some embodiments of the disclosure.

FIGS. 9A-9B-14A-14B depict example processes of forming at least part of a memory device in a plan view and a cross-sectional view according to some embodiments of the disclosure.

FIG. 15 depicts a schematic configuration of an example semiconductor system according to some embodiments of the disclosure.

### DETAILED DESCRIPTION

Various example embodiments of the disclosure and combinations thereof will be described below in detail with reference to the accompanying drawings. The following detailed descriptions refer to the accompanying drawings that show, by way of illustration, specific aspects in which embodiments of the disclosure may be practiced. These embodiments are described in sufficient detail to enable those skilled in the art to practice the disclosure. Other embodiments may be utilized, and structure, logical and electrical changes may be made without departing from the scope of the disclosure. The various embodiments disclosed herein are not necessarily mutually exclusive, as some disclosed embodiments can be combined with one or more other disclosed embodiments to form new embodiments.

In the descriptions, common or related elements and elements that are substantially the same are denoted with the same signs, and the descriptions thereof may be reduced or omitted. In the drawings, some of the same signs may be omitted for the same or substantially the same elements for ease of illustration. In the drawings, the dimensions and dimensional ratios of each unit do not necessarily match the actual dimensions and dimensional ratios in the embodiments.

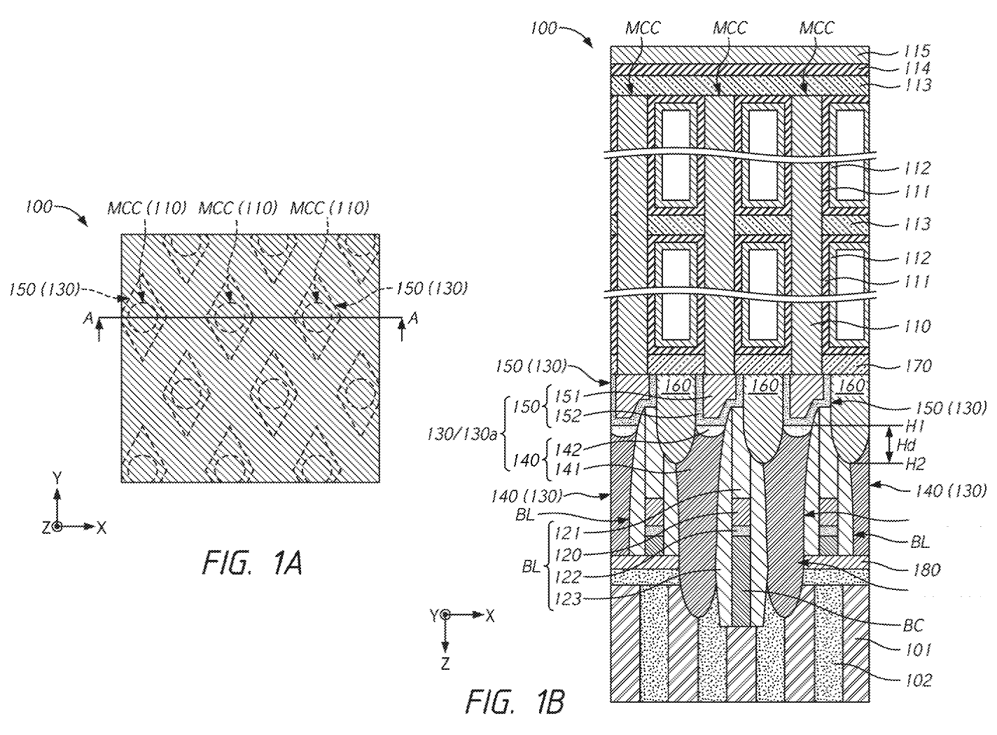

FIGS. 1A and 1B depict an example configuration of at least part of a memory device 100 in a plan view and a cross-sectional view, respectively, according to some embodiments of the disclosure. The cross-sectional view in FIG. 1B corresponds to line A-A in FIG. 1A. The size, position, and other aspects of the cross-sectional view may not necessarily match those of the plan view in the drawings. The memory device 100 may be a dynamic random-access memory (DRAM). The memory device 100 may be one example of a semiconductor device. The memory device 100 may be one example of an apparatus. The memory device 100 may include memory cell capacitors MCC, contact plugs 130, and insulating members 160. The contact plugs 130 may couple the associated memory cell capacitors MCC to corresponding active regions formed in a semiconductor substrate 101. The insulating members 160 may be provided between neighboring contact plugs 130 and may isolate them from each other. The memory device 100 may further include bit lines BL coupled to other corresponding active regions of the semiconductor substrate 101. The insulating members 160 may be provided between neighboring bit lines BL.

The memory device 100 includes a plurality of memory cell capacitors MCC. The memory cell capacitors MCC each may include a conductive pillar 110. The conductive pillar 110 may serve as a lower (or bottom) capacitor electrode and may include a conductive material, such as a metal (e.g., titanium nitride (TiN)). The conductive pillar 110 may also be referred to as a metal pillar. The memory cell capacitors MCC each may further include a dielectric layer 111 and a conductive layer 112. The conductive layer 112 may serve as an upper (or top) capacitor electrode and may include the same material as the lower electrode, such as TiN. The dielectric layer 111 may be sandwiched between the lower and upper electrodes and may include an insulating material, such as a high-k dielectric material (e.g., Zirconium Oxide (ZrO₂) and hafnium oxide (HfO₂)). The memory cell capacitors MCC may be pillar-type capacitors. The depicted example configuration may further include insulating layers 113. The insulating layers 113 may include an insulating material, such as a nitride (e.g., silicon nitride (Si₃N₄ or simply SiN)). Another high-k layer 114 and another conductive layer 115 may also be provided on the memory cell capacitors MCC and neighboring structures. In some instances, additional insulating layers and/or conductive layers may be provided as appropriate. The memory cell capacitors MCC may be arranged at intersections of word lines (not separately depicted) and bit lines BL. The memory cell capacitors MCC may be arranged in a matrix. Each memory cell capacitor MCC may form at least part of a memory cell to store data by accumulating electric charges therein and to be accessed via the associated word line and bit line during data write and read operations. Each memory cell capacitor MCC may include a vertical capacitor structure that extends in a vertical direction, which may be for example a Z-axis direction in the drawing. Bit lines BL (may also be referred to as digit lines or data lines) may be arranged in parallel with each other in a first horizontal direction, which may be for example an X-axis direction in the drawing, and each may extend in a second horizontal direction, which may be for example a Y-axis direction in the drawing, perpendicular (or substantially perpendicular within reasonable tolerances of fabrication, measurement, etc.) to the first horizontal direction. Word lines may be arranged in parallel with each other in the Y-axis direction and each may extend in the X-axis direction, intersecting with bit lines BL in the plan view (for example, in a plane along the X-axis direction and the Y-axis direction).

Each bit line BL includes a bit line structure, which includes at least a conductive part 120. The conductive part 120 may include a conductive material, such as a metal (e.g., tungsten (W)). The conductive part 120 may also be referred to as a bit line metal. On the conductive part 120 is an insulating layer 121 including an insulating material, such as a nitride (e.g., SiN). The insulating layer 121 may serve as a mask layer or a cap layer. Under the conductive part 120 is another conductive part 122 including a conductive material, such as a metal (e.g., TiN). The conductive part 122 may also be referred to as a barrier metal. Furthermore, an insulating side wall 123 is provided on side surfaces of the conductive parts 120 and 122 and the insulating layer 121. The insulating side wall 123 may include one or more insulating films. One insulating film may include an insulating material, such as an oxide (e.g., silicon oxide (SiO₂ or simply SiO)). Another insulating film may include another insulating material, such as a nitride (e.g., SiN). The insulating side wall 123 may be part of the bit line structure. The insulating side wall 123 may serve as an insulating spacer. Other elements, films, layers, or the like may be included in the bit line structure as appropriate. The bit lines BL may be coupled to active regions (one of source/drain regions of a memory cell access transistor, for example) formed in the semiconductor substrate 101 via bit line contacts BC. Each bit line contact BC may include a conductive material, such as polycrystalline silicon or polysilicon (poly-Si). A lower portion of the bit line contact BC extends into the semiconductor substrate 101 and is coupled to the active region. An upper portion of the bit line contact BC is coupled to the conductive part 122 of the associated bit line structure. The bit line contact BC may be surrounded by the extended part of the insulating side wall 123 of the bit line structure. The memory device 100 may also include isolation structures 102, such as shallow trench isolations STI, formed in the semiconductor substrate 101. The isolation structures may include an insulating material, such as an oxide (e.g., SiO).

The memory device 100 includes a plurality of contact plugs 130 arranged in a matrix corresponding to the matrix of the memory cell capacitors MCC. The contact plugs 130 couple the respective memory cell capacitors MCC to other active regions (another of the source/drain regions of the access transistor, for example) of the semiconductor substrate 101. Each contact plug 130 includes a lower conductive plug 140 and an upper conductive plug 150, together coupling the associated memory capacitor MCC to the corresponding active region of the semiconductor substrate 101. The lower conductive plug 140 extends in the vertical direction (the Z-axis direction in the drawing) into the semiconductor substrate 101 and is coupled to the active region. The upper conductive plug 150 is provided on the lower conductive plug 140 and coupled to the memory cell capacitor MCC. The upper conductive plug 150 includes a bottom part contacting a top part of the lower conductive part 140. In the depicted example, a center of the lower conductive plug 140 and a center of the upper conductive plug 150 are shifted from each other horizontally.

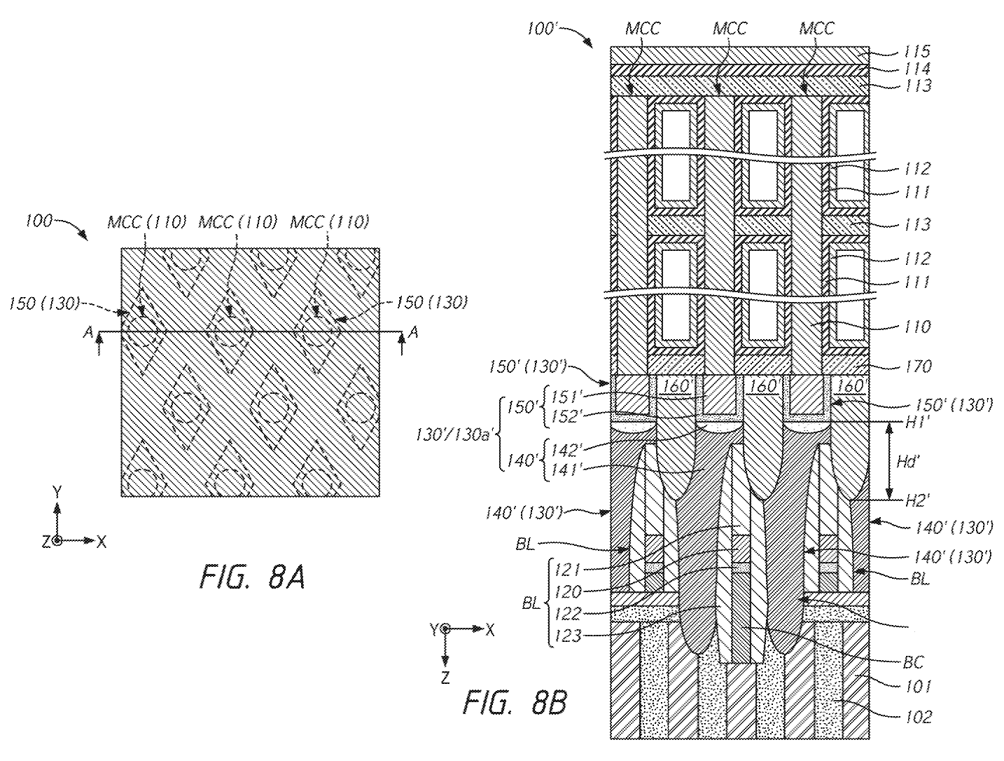

The memory device 100 further includes a plurality of insulating members 160. The insulating members 160 are adjacent to the respective contact plugs 130. Each insulating member 160 is provided between neighboring contact plugs 130 (such as first and second contact plugs 130a and 130b shown in the drawing). The insulating member 160 is located between neighboring bit lines BL. The insulating member 160 may include an insulating material, such as a nitride (e.g., silicon nitride (SiN)). The insulating member 160 isolates the neighboring contact plugs 130 from each other. The insulating member 160 prevents a short circuit between the neighboring contact plugs 130. In the depicted example, the insulating member 160 is adjacent to the lower and upper conductive plugs 140 and 150 of the first contact plug 130a on one side and to the lower and upper conductive plugs 140 and 150 of the second contact plug 130b on the opposite side. The insulating member 160 extends into part of the lower conductive plug 140. The insulating member 160 may form an insulating pillar vertically extending between the contact plugs 130a and 130b. The insulating member 160 isolates and/or insulates at least the upper conductive plug 150 of the first contact plug 130a from the upper conductive plug 150 of the second contact plug 130b. In some instances, the insulating member 160 may also isolate and/or insulate the lower conductive plug 140 of the first contact plug 130a from the lower conductive plug 140 of the second contact plug 130b (see FIG. 8B, for example). Accordingly, the insulating member 160 prevents a short circuit between the neighboring first contact plug 130a and second contact plug 130b.

The lower conductive plug 140 and the upper conductive plug 150 of each of the contact plug 130 may include a conductive material, such as polysilicon (poly-Si), and a different conductive material, such as a metal, respectively. The lower conductive plug 140 and the upper conductive plug 150 may also be referred to as a polysilicon plug and a metal plug, respectively. The lower conductive plug 140 may further include another conductive material, such as cobalt (Co) or cobalt silicide (CoSi₂). The lower conductive plug 140 includes poly-Si as a lower part 141 coupled to the active region of the semiconductor substrate 101 and Co/CoSi₂ as an upper part 142 coupled to the upper contact plug 150. The upper conductive plug 150 may include a first metal part 151 and a second metal part 152. In the depicted example, the first metal part 151 is located under the memory cell capacitor MCC. The first metal part 151 may include a first metal material, such as tungsten (W). The first metal part 151 is directly coupled to the conductive pillar 110 of the memory cell capacitor MCC. The second metal part 152 is provided on bottom and side surfaces of the first metal part 151. The second metal part 152 is provided on and in contact with a top surface of the lower conductive plug 140. The second metal part 152 may include a second metal material, such as titanium (T) or titanium nitride (TiN), different from the first metal material. The upper conductive plug 150 may be positioned such that the center thereof is shifted from the center of the lower conductive plug 140 horizontally.

In the depicted example according to the present embodiments, the respective memory cell capacitors MCC and contact plugs 130 are directly coupled to each other, without any intermediate conductive layers, films, or the like, such as a redistribution layer. More specifically, a top part of the upper conductive plug 150 of each contact plug 130 contacts a bottom part of the conductive pillar 110 of the associated memory cell capacitor MCC. The memory device 100 may further include an insulating layer 170 between the memory cell capacitors MCC and the contact plugs 130 and insulating members 160. The insulating layer 170 may include one or more insulating layers stacked on one another. The insulating layer 170 may include an insulating material, such as silicon oxycarbide/oxycarbide glass (SiOC) and/or a nitride (e.g., SiN). The conductive pillar 110 may extend through the insulating layer 170. The bottom part of the conductive pillar 110 may be surrounded by the insulating layer 170. The bottom part of the conductive pillar 110 may penetrate the insulating layer 170, and may be exposed at a layer bottom surface, abutting the top surface of at least the first metal part 151 of the upper conductive plug 150. In some instances, the bottom part of the conductive pillar 110 may also be in contact with the second metal part 152 of the upper conductive plug 150. The present embodiments therefore do not require additional coupling elements, such as a redistribution layer, between the contact plug 130 and the memory cell capacitor MCC. Instead, the present embodiments enable direct coupling between the two via the upper conductive plug 150 of the contact plug 130. In cases where a redistribution layer is provided in addition to a contact plug for cell capacitor coupling, the margin for open or short defects between the redistribution layer and other conductive elements (such as a bit line) is reduced due to device downsizing. In contrast, the example configuration according to the present embodiments eliminates the need for a redistribution layer and can effectively prevent such open or short defects while still achieving the device downsizing and also reducing the time and cost of device fabrication. As a result, the production yield of memory devices can be increased. Furthermore, for example, the upper conductive plug 150 can be provided by forming a plug hole and then filling the plug hole with the metal material after formation of the insulating member 160. This process can prevent defects to the lower conductive plug 140, especially defects to the upper part 142 (such as the Co/ CoSi₂ part) above the lower part (such as the poly-Si part) 141 of the lower conductive plug 140 during the device fabrication. The resultant structure including the contact plug 130 and the insulating member 160 according to the present embodiments exhibits a configuration in which the bottom part of the upper conductive plug 150 of the contact plug 130 is higher than a bottom part of the insulating member 160. As shown in FIG. 1B, height H1 of the bottom part of the upper conductive plug 150 is greater than height H2 (H1>H2) of the bottom part of the insulating member 160 above the semiconductor substrate 101. More specifically, the second metal part 152 of the upper conductive plug 150 is located higher than the bottom part of the insulating member 160 in the vertical/Z-axis direction. H1 and H2, and hence height difference Hd, may be adjusted according to process conditions. Additionally, in some instances, the top part of the upper conductive plug 150 may be positioned at the same height as a top part of the insulating member 160 above the semiconductor substrate 101. A top surface of the upper conductive plug 150 and a top surface of the insulating member 160 may be flush or substantially flush with each other. The processes that achieve the above configuration will be described in further detail below. A center of the lower conductive plug 140 may not align with a center of the upper conductive plug 150 in the horizontal direction. Even if the active regions formed in the semiconductor substrate 101 and the memory cell capacitors MCC provided above the semiconductor substrate 101 do not alight with each other, the contact plugs 130 including the shifted lower and upper conductive plugs 140 and 150 may appropriately couple the respective memory cell capacitors MCC and active regions.

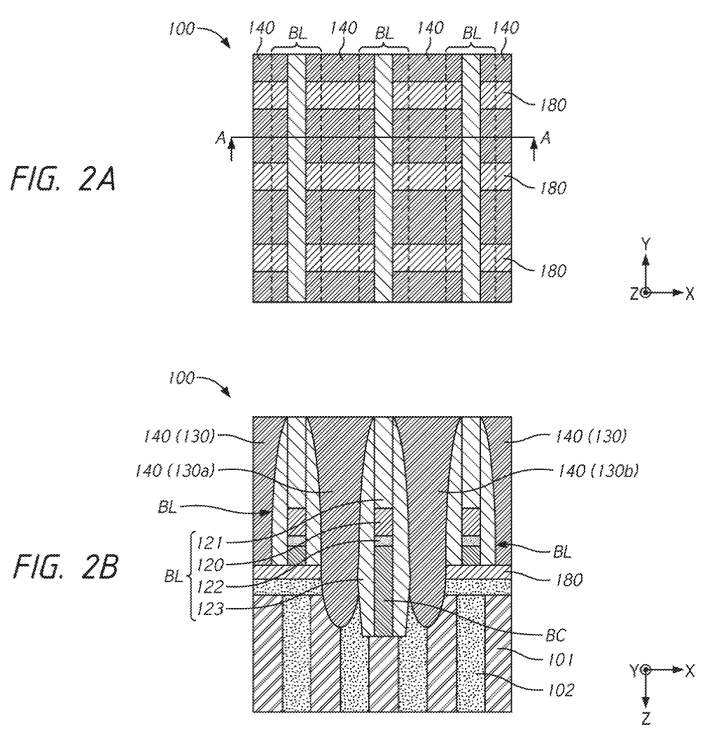

FIGS. 2A-2B-7A-7B depict example processes of forming at least part of the memory device 100 in a plan view and a cross-sectional view according to some embodiments of the disclosure. FIGS. 2A-7A depict the processes in the plan view. The cross-sectional views in FIGS. 2B-7B correspond to line A-A in FIGS. 2A-7A. The size, position, and other aspects of the cross-sectional view may not necessarily match those of the plan view in the drawings. The memory device 100 of these figures corresponds to the memory device 100 of FIGS. 1A-1B. An example method to form at least part of a memory device according to some embodiments of the disclosure may include the processes described below.

First, as shown in FIGS. 2A and 2B, a part of the memory device 100 is formed, including, for example, the bit line contacts BC and the bit lines/bit line structures BL (hereinafter referred to as bit line structures BL) on the semiconductor substrate 101. Between the neighboring bit line structures BL are the lower conductive plugs 140 of the contact plugs 130 each extending vertically toward the semiconductor substrate 101. In the depicted example, the lower conductive plugs 140 of the neighboring contact plugs 130a and 130b with one bit line structure BL therebetween extend into the semiconductor substrate 101 and reach the active regions of the semiconductor substrate 101. The lower conductive plugs 140 of the other contact plugs 130 may stop at an insulating layer 180 provided above the semiconductor substrate 101. Plug holes (not separately depicted) may be first formed between the bit line structures BL and then filled with the conductive material, such as poly-Si, to form the lower conductive plugs 140. At this stage, the top surface of each lower conductive plug 140 is made flush or substantially flush with the top surface of the adjacent bit line structure BL. Any conventional methods, such as photolithography, etching, deposition, and polishing, may be used as appropriate to form the bit line structures BL and the lower conductive plugs 140. Later developed techniques may also be applicable as appropriate. Other elements, layers, and/or structures may also be formed, depending on device specifications, designs, or the like. The depicted example shows a plurality of insulating layers 180 each including an insulating material, such as SiN. The insulating layers 180 run in the direction orthogonal or substantially orthogonal to the bit line direction and may electrically separate the lower conductive plugs 140.

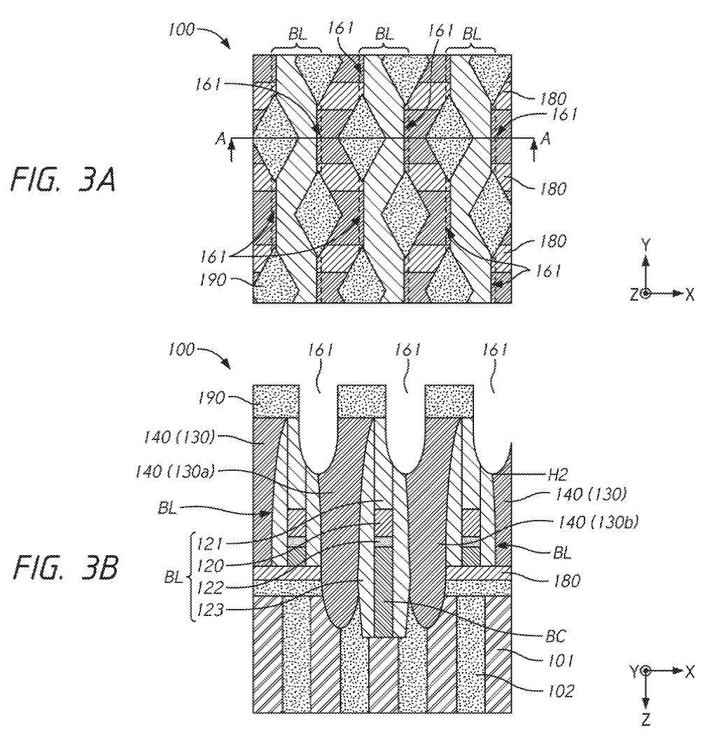

Next, as shown in FIGS. 3A and 3B, an insulating layer 190 is first provided, and then pillar holes 161 are formed at positions corresponding to the associated bit line structures BL and the lower conductive plugs 140 of the associated contact plugs 130. In subsequent processes, insulating members 160 will be formed in a pillar shape, extending vertically within the pillar holes 161. In the depicted example, an upper portion of the bit line structure BL and an upper portion of the lower conductive plug 140 are removed such that the pillar hole 161 extends at least partway into the lower conductive plug 140 in the vertical direction (the Z-axis direction in the drawing). The insulating layer 190 may be formed by for example depositing an insulating material, such as an oxide (e.g., SiO). The insulating layer 190 that includes an oxide may serve as an oxide mask. The pillar holes 161 may be formed using patterning techniques, such as photolithography and etching. The conditions for hole patterning may be appropriately determined to achieve a specific depth for each pillar hole 161. Height H2 of the bottom part of the pillar hole 161 determines or substantially determines the height of the bottom part of the to-be-formed insulating member 160.

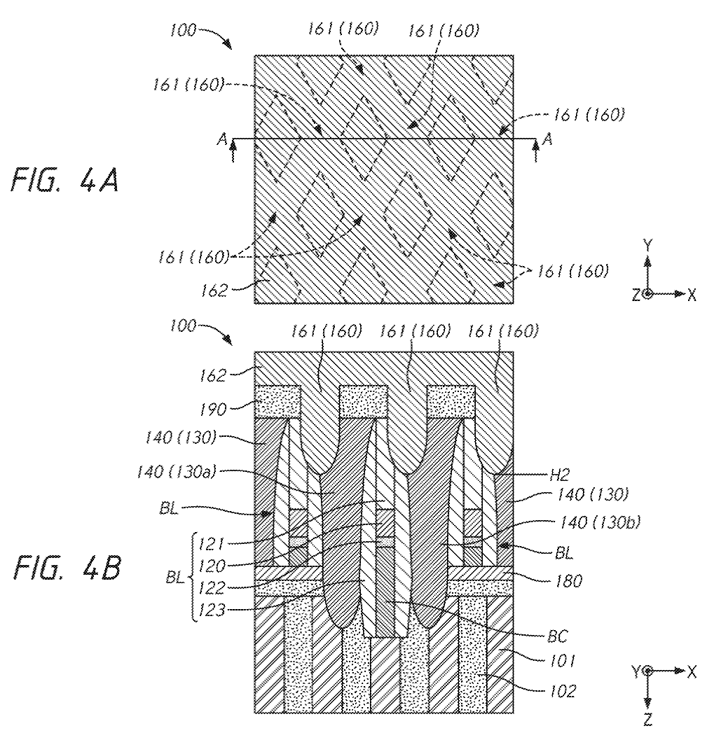

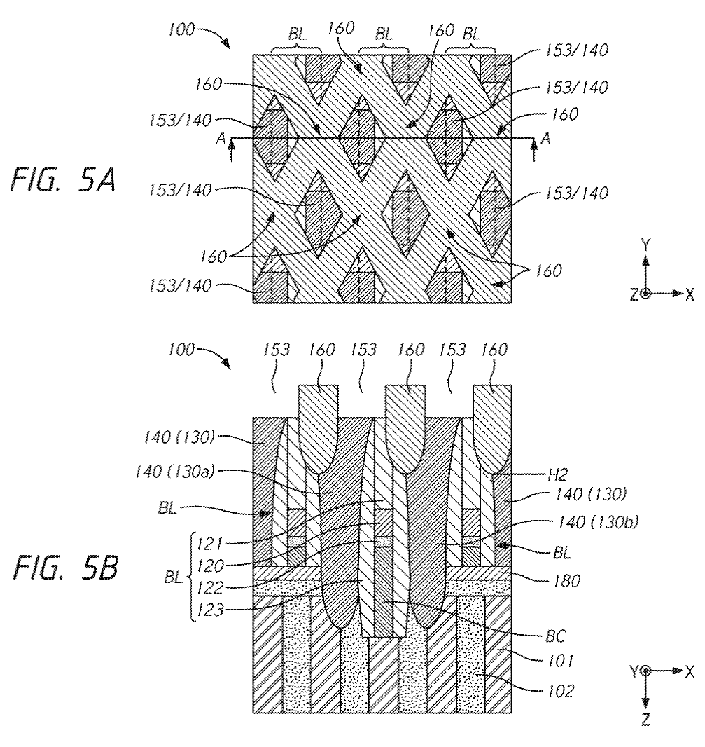

As shown in FIGS. 4A and 4B, an insulating material 162, such as a nitride (e.g., SiN), is deposited to fill the pillar holes 161 and form the insulating members (hereinafter referred to as insulating pillars) 160 therein that extend vertically partway into the associated lower conductive plugs 140 and bit line structures BL. Subsequently, as shown in FIGS. 5A and 5B, the excessive insulating material 162 and the insulating layer/insulating material 190 are removed by for example etching. The removal of the insulating material 190 forms plug holes 153 between neighboring insulating pillars 160, where the upper conductive plugs 150 of the contact plugs 130 will be formed in later processes. The etching conditions, such as etchant and etching time, may be appropriately adjusted to ensure the removal of the desired amount of target material and to form the intended structure of the insulating pillars 160 and the plug holes 153.

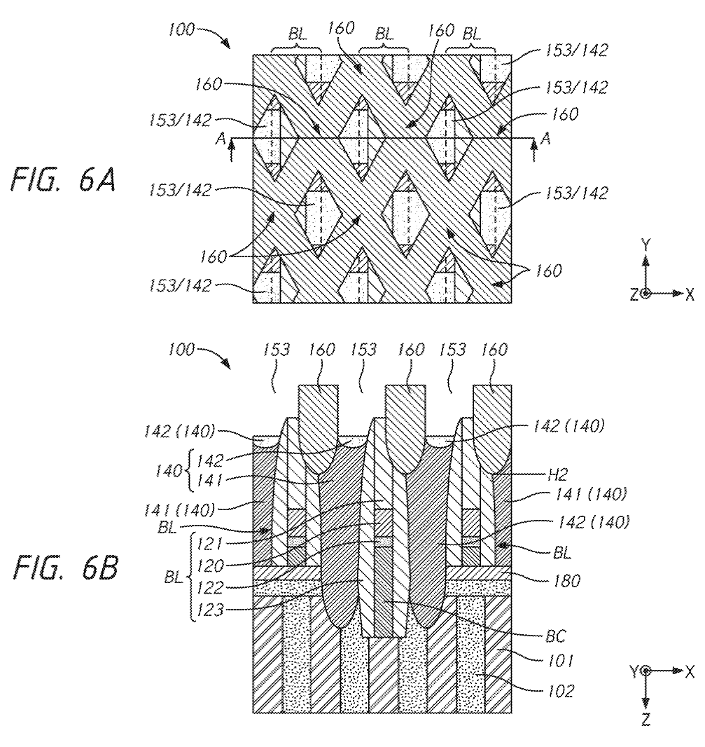

As shown in FIGS. 6A and 6B, upper portions of the respective lower conductive plugs 140 are removed, for example by etching, to make the plug holes 153 deeper. An etchant with higher selectivity for the conductive material (poly-Si) of the lower conductive plugs 140 than for the insulating materials of the insulating pillars 160 may be used. Other factors, such as etching time, may also be appropriately determined to ensure the removal of an appropriate amount of the target material. The top portions of the respective bit lines BL remain unetched and protrude into the plug holes 153. The bit lines BL and the insulating pillars 160 remain adjacent to each other. Subsequently, cobalt (Co) or cobalt silicide (CoSi₂) is deposited onto the top surfaces of the respective lower conductive plugs 140. This process forms the Co/CoSi₂ upper part 142 on the poly-Si lower part 141, together constituting each lower conductive plug 140.

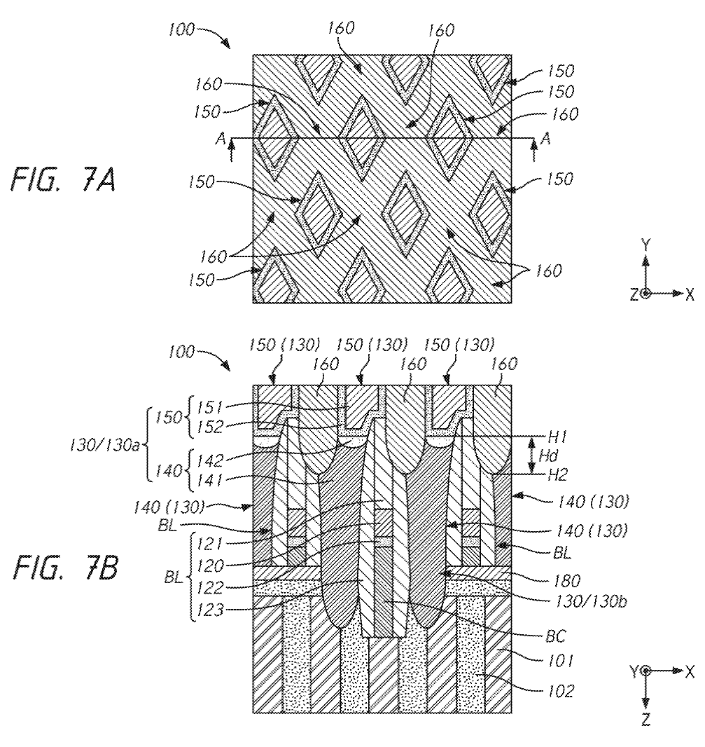

Then, as shown in FIGS. 7A and 7B, the upper conductive plugs 150 are formed in the respective plug holes 153. For example, first, the metal material (e.g., Ti or TiN) forming the second metal part 152 is deposited as a film in the plug hole 153. Second, the metal material (e.g., W) forming the first metal part 151 is deposited on the second metal part 152. The excess metal materials may be removed for example by polishing, such as chemical mechanical polishing (CMP). The top surfaces of the metal parts (151, 152) may be polished to be flush with each other. The resultant upper conductive plugs 150 each have the bottom surface of the second metal part 152 abutting the top surface of the upper part 142 of the lower conductive plug 140. In the depicted example, the lower surface of the second metal part 152, which is continuous with the bottom surface, contacts the top surface of the upper portion of the bit line BL. The bottom part (height H1) of the upper conductive plug 150 is positioned higher than the bottom part (height H2) of the insulating pillar 160, while the top part of the upper conductive plug 150 is at the same height as the top part of the insulating pillar 160 above the semiconductor substrate 101. The bottom surface of the second metal part 152, which contacts the top surface of the upper part 142 of the lower conductive plug 140, is positioned higher than the bottom surface of the insulating pillar 160, which extends partway into the lower part 141 of the lower conductive plug 140. The top surfaces of the first and second metal parts 151 and 152 of the upper conductive plug 150 and the top surface of the insulating pillar 160 may be flush or substantially flush with each other. The upper conductive plug 150 and the insulating pillar 160 extend downwardly from the same height position, but the insulating pillar 160 extends deeper. Consequently, the contact plugs 130 including the lower contact plugs 140 and the upper contact plugs 150 are formed, maintaining the above-described positional relationship with the insulating member 160.

Following the above process, as shown in FIGS. 1A and 1B, the memory cell capacitors MCC are formed at the positions corresponding to the contact plugs 130, more specifically to the upper conductive plugs 150 of the contact plugs 130. For example, after the insulating layer 170 is deposited, covering the upper conductive plugs 150 and the insulating pillars 160, the conductive pillar 110 is formed, penetrating the insulating layer 170 to reach the upper conductive plugs 150. The dielectric layer 111 and the conducive layer 112 are then formed between the neighboring conductive pillars 110. The conductive pillar 110, the dielectric layer 111, and the conductive layer 112 may be formed by deposition of their respective materials, which may include a metal (e.g., titanium nitride (TiN)), a high-k material (e.g., ZrO₂ and HfO₂), and another metal (e.g., TiN), respectively. The memory cell capacitor MCC is hence formed, including the conductive pillar 110 and the conductive layer 112, which serve as the lower (bottom) and the upper (top) electrodes, respectively, with the dielectric layer 111 sandwiched between them. Other layers, including but not limited to the insulating layer 113, the high-k layer 114 and the conductive layer 115, are also formed as needed. The formation of the memory cell capacitors MCC and other layers may be carried out using conventional methods/processes, such as deposition, etching, and polishing. Later developed techniques may also be applicable as appropriate. Accordingly, as described above, the memory cell capacitors MCC, more specifically their conductive pillars 110, are directly coupled to the associated lower contact plugs 140 via the upper conductive plugs 150, without any additional conductive layers, films, or similar elements, such as a redistribution layer. Consequently, the present embodiments can effectively reduce device fabrication time and cost. Furthermore, while in cases where an intermediate conductive element, such as a redistribution layer is formed between a contact plug and a memory cell capacitor, short and open defects may occur between a cell contact and a redistribution layer, in the present embodiments, such short and open defects can be effectively prevented. For example, according to the present embodiments, since the neighboring contact plugs 130 are fully isolated by the insulating pillars 160, shorts circuit can be prevented. Additionally, because the upper part (Co/ CoSi₂) 142 of the lower conductive part 140 of each contact plug 130 remains undamaged during subsequent patterning, open defects can also be avoided. This effectively improves the device fabrication yield.

FIGS. 8A and 8B depict an example configuration of at least part of a memory device 100’ in a plan view and a cross-sectional view, respectively, according to some embodiments of the disclosure. While FIGS. 1A and 1B illustrate the case where the top part of the lower conductive plug 140 is lower than the top part of the adjacent bit line structure BL, FIGS. 8A and 8B show the case where the top part of the lower conductive plug 140’ is higher than the top part of the adjacent bit line structure BL. More specifically, the lower part 141’ of the lower conductive part 140’ in the memory device 100’ is elongated above the bit line structure BL, and the top surface of the upper part 142’ is raised higher than that in the memory device 100. In the memory device 100’, the raised upper part 142’ does not interfere with the top part of the bit line structure BL, unlike in the memory device 100 where the upper part 142 contacts the top part of the bit line structure BL. Therefore, the area size of the upper part 142’ in the memory device 100’ is increased compared to that of the upper part 142 in the memory device 100. This increase in the area size of the upper part 142’ of the lower conductive plug 140’ effectively reduces the contact resistance with the upper conductive plug 150’ (more specifically, with the second metal part 152’ under the first metal part 151’). In the example configuration depicted in FIGS. 8A and 8B, the bottom part (H1’) of the upper conductive plug 150’ is maintained higher than the bottom part (H2’) of the insulating pillar 160’ with the height difference Hd’, while the top part of the upper conductive plug 150’ is maintained at the same height as the top part of the insulating pillar 160’ above the semiconductor substrate 101. The insulating pillar 160’ in the memory device 100’ is longer than the insulating pillar 160 in the memory device 100 in the vertical/Z-axis direction.

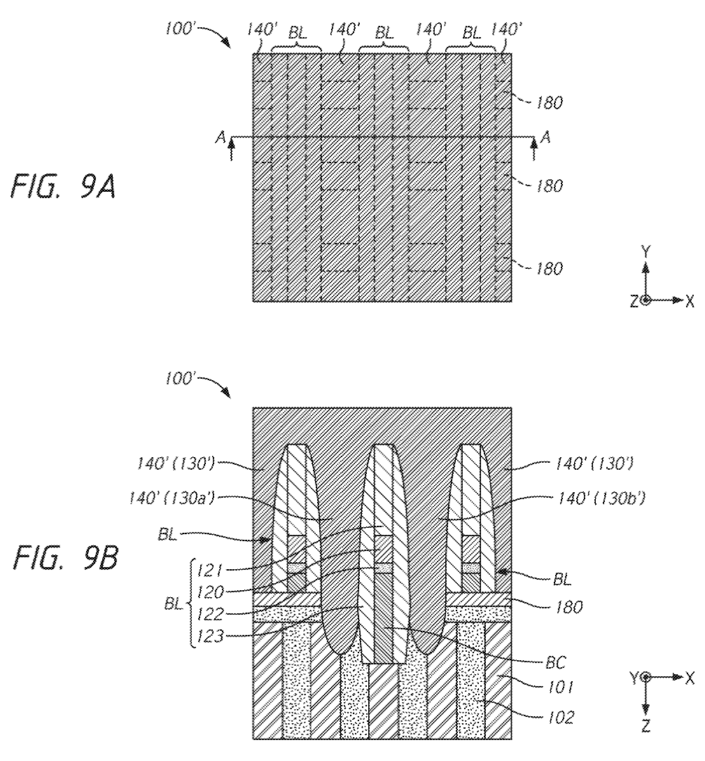

FIGS. 9A-9B-11A-14B depict example processes of forming at least part of the memory device 100’ in the plan view and the cross-sectional view according to some embodiments of the disclosure. First, similarly to the example of FIGS. 2A and 2B, as shown in FIGS. 9A and 9B, a part of the memory device 100’ is formed, including the bit line contacts BC and the bit line structures BL on the semiconductor substrate 101 as well as the lower conductive plugs 140’ of contact plugs 130’ between the neighboring bit line structures BL. Unlike the lower conductive plugs 140 in the example of FIGS. 2A and 2B, the lower conductive plugs 140’ in the example of FIGS. 9A and 9B each have its top surface positioned higher than the top surface of the bit line structure BL. For example, the lower conductive plugs 140’ may be formed by first patterning plug holes between neighboring bit line structures BL, and then depositing the conductive material (e.g., polysilicon) to fill the plug holes. At least some, if not all, of the conductive material may be left unremoved, resulting in the lower conductive plugs 140’ higher than the bit line structures BL above the semiconductor substrate 101.

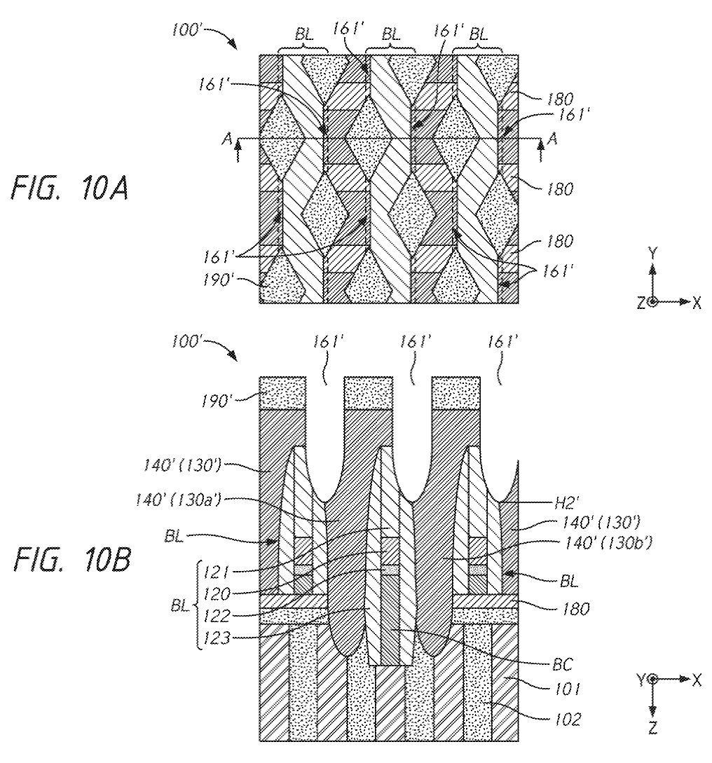

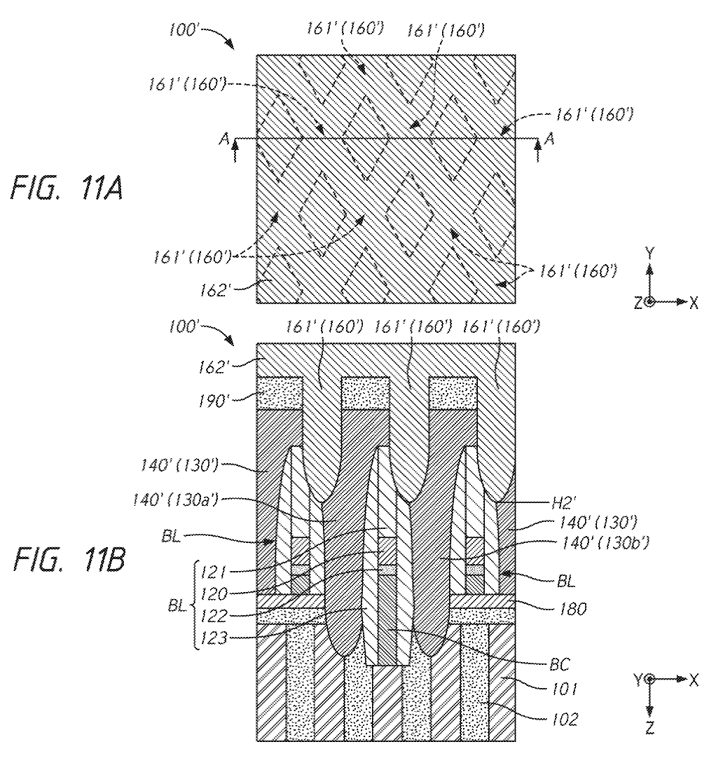

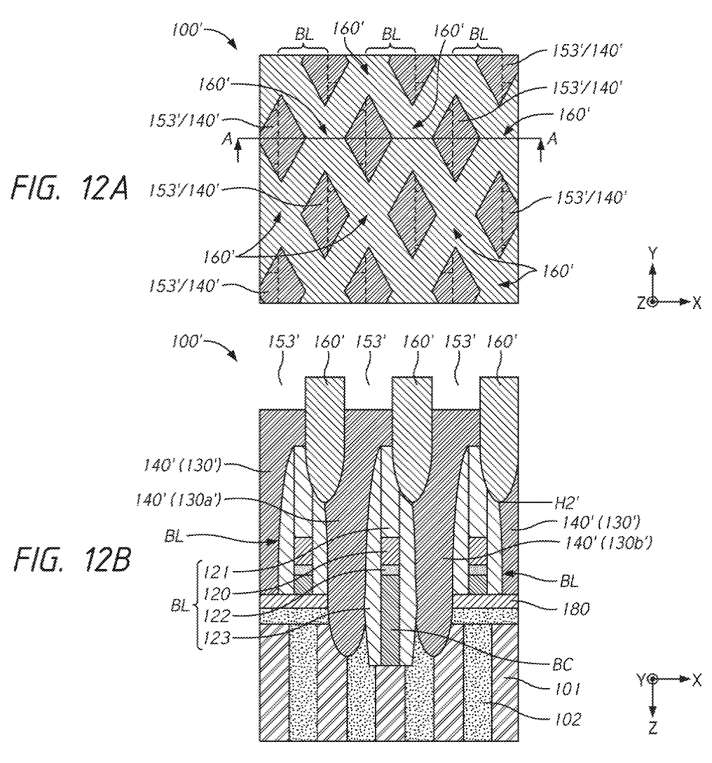

Then, as shown in FIGS. 10A and 10B, the insulating layer 190’ is provided on the top surface of the remaining conductive material/layer of the lower conductive plugs 140’, and the pillar holes 161’ are patterned to penetrate the insulating layer 190’ and extend through the top portions of the lower conductive plugs 140’ and partway into the underlying bit line structures BL. This process is similar to the example of FIGS. 3A and 3B, except that due to the increased height of the lower conductive plugs 140’, the pillar holes 161’ are longer in the vertical direction compared to the pillar holes 161. In some instances, the height position (H2’) of the bottom part of each pillar hole 161’ may be the same or substantially the same as that of the bottom part (H2) of the pillar hole 161 above the semiconductor substrate 101. Subsequently, similarly to the example of FIGS. 4A-4B and 5A-5B, and as shown in FIGS. 11A-11B and 12A-12B, the insulating material 162’ (e.g., SiN) is deposited to at least fill the plug holes 153’, and then the insulating materials 162’ and 190’ are removed, to form the insulating pillars 160’ within the respective pillar holes 161’ and the plug holes 153’ between the neighboring insulating pillars 160’. In contrast with the previous example, each insulating pillar 160’ extends vertically from a higher position and is therefore longer than the insulating pillar 160. Furthermore, each plug hole 153’ stops at a higher position above the lower conductive plug 140, compared to the plug hole 153 that reaches lower than the top part of the conductive plug 140. The etching conditions may be appropriately determined to achieve the intended structure of the insulating pillars 160’s and the plug holes 153’.

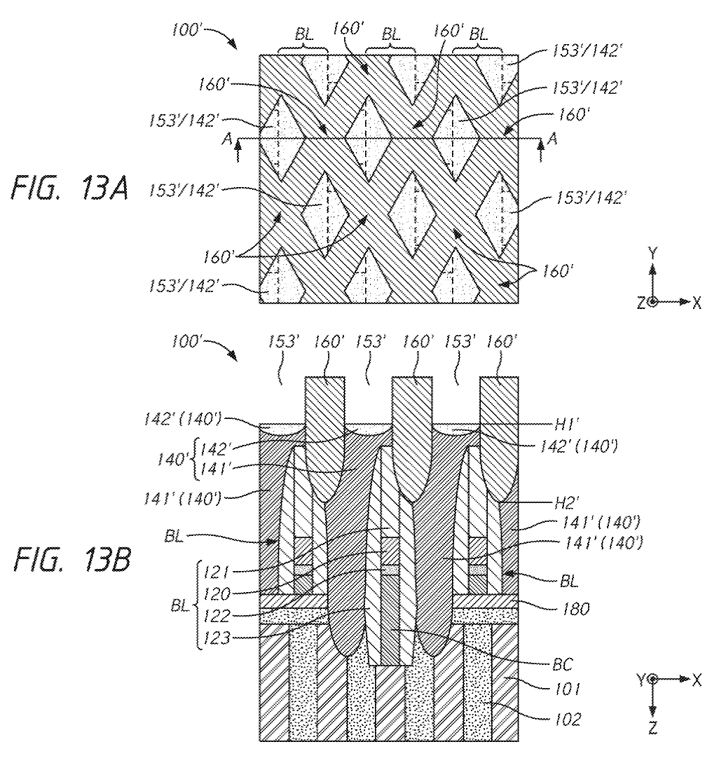

Subsequently, as shown in FIGS. 13A and 13B, the plug holes 153 are made deeper by removing the upper portions of the respective lower conductive plugs 140’, and then the cobalt (Co) or cobalt silicide (CoSi₂) is deposited onto the lowered bottom surfaces of the plug holes 153, which are the top surfaces of the lower conductive plugs 140. This process forms the Co/CoSi₂ upper parts 142’ on the poly-Si lower parts 141’, together constituting the respective lower conductive plugs 140 in a manner similar to the example of FIGS. 6A and 6B, except that the top surface of each of the lower conductive plugs 140’ which is the top surface of each of the upper parts 142’ is positioned higher (H1’) than the top surface of each of the bit line structures BL. This height (H1’) substantially defines the height of the bottom surface of the upper conductive plug 150’ to be formed in the plug hole 153 in the subsequent process. In the resultant configuration of the memory device 100’, the upper part 142’ of the lower conductive plug 140’ does not interfere with the upper portion of the bit line structure BL, unlike in the memory device 100 where the upper part 142 contacts the top part of the bit line structure BL. Therefore, the area size of the upper part 142’ in the memory device 100’ is increased compared to that of the upper part 142 in the memory device 100. This increase in the area size of the upper part 142’ of the lower conductive plug 140’ effectively reduces the contact resistance with the upper conductive plug 150’.

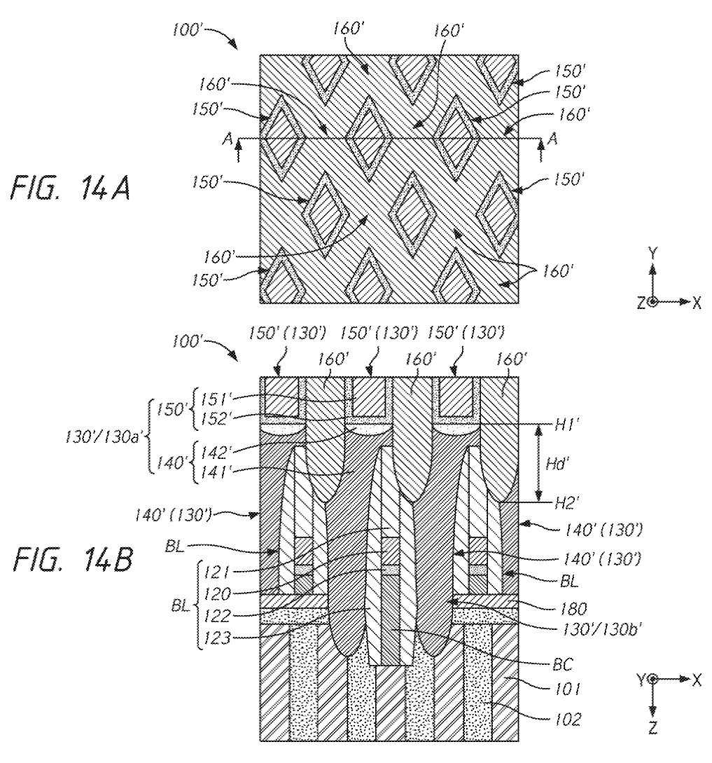

Finally, as shown in FIGS. 14A and 14B, the upper conductive plugs 150’ are formed by depositing the metal materials of the first and second metal parts 151’ and 152’ (e.g., W and Ti/TiN, respectively) in the plug holes 153’ on top of the corresponding lower conductive plugs 140’. The upper conductive plugs 150’ and the lower conductive plugs 140’ together constitute the respective contact plugs 130’. The upper conductive plugs 150’ and the lower conductive plugs 140’ of neighboring contact plugs 130’ (e.g., 130a’ and 130b’ in the drawing) are isolated from each other by the insulating pillar 160’. The resultant structure in FIGS. 14 and 14B is similar to that in FIGS. 7A and 7B, except that due to the raised top surfaces of the lower conductive plugs 140’, the upper conductive plugs 150’ do not contact or interfere with the underlying bit line structures BL, achieving larger, more secured contact areas with the lower conductive plugs 140’ than the example of FIGS. 7A and 7B. The height difference Hd’ (H1’>H2’) is greater than Hd (H1>H2). As in the example of FIGS. 1A and 1B, the memory cell capacitors MCC are then formed at the positions corresponding to the contact plugs 130’, more specifically to the upper conductive plugs 150’ of the contact plugs 130’ as shown in FIGS. 8A and 8B. The memory cell capacitors MCC are directly coupled to the upper conductive plugs 150’ of the contact plugs 130’ without any intermediate conductive elements, such as a redistribution layer, and further coupled to the active regions of the semiconductor substrate 101 via the associated contact plugs 130’.

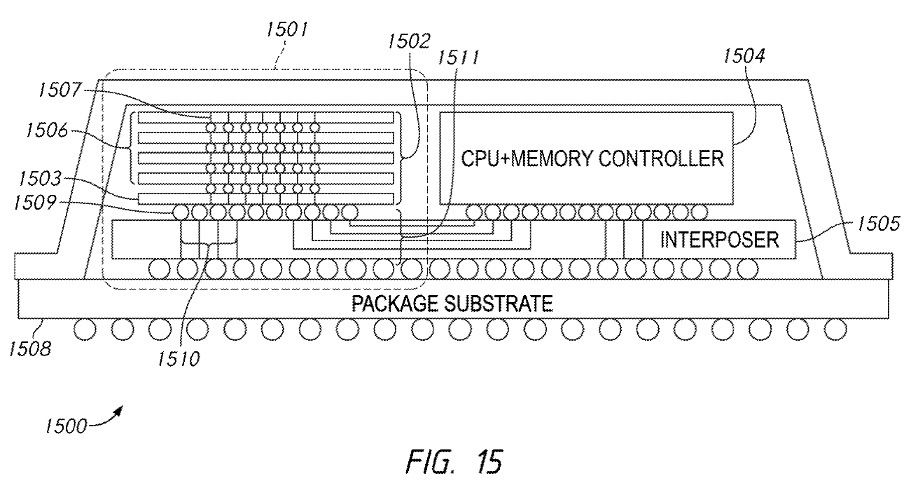

FIG. 15 depicts a schematic configuration of an example semiconductor system 1500 according to some embodiments of the disclosure. The semiconductor system 1500 includes a semiconductor memory device 1501 in an embodiment of the disclosure. In some embodiments of the disclosure, the semiconductor memory device 1501 may include the memory device 100 of FIGS. 1A-1B or the memory device 100’ of FIGS. 8A-8B. The semiconductor system 1500 may also include a central processing unit (CPU) and memory controller 1504, which may be a controller chip, on an interposer 1505 on a package substrate 1508. The interposer 1505 may include one or more power lines 1510 which may supply power supply voltage from the package substrate 1508. The interposer 1505 may include a plurality of channels 1511 that may interconnect the CPU and memory controller 1504 and the semiconductor memory device 1501. The semiconductor memory device 1501 may be a DRAM. The memory controller 1504 may provide a clock signal, a command signal, and may further transmit and receive data signals. The plurality of channels 1511 may transmit the data signals between the memory controller and the memory device 1501.

The semiconductor memory device 1501 may include a plurality of dies (or chips) 1502 including at least one interface (IF) die (or chip) 1503 and a plurality of memory core dies (or chips) 1506 stacked with each other. A number of the memory core dies 1506 may not be limited to four as in the illustrated example, and may be more or fewer as appropriate. Each of the memory core dies 1506 may include a plurality of memory cells and circuitries accessing the memory cells. For example, the memory cells may be DRAM cells. The memory cells may be arranged in array. The semiconductor memory device 1501 may include conductive vias 1507 which couple the IF die 1503 and the memory core dies 1506 by penetrating the IF die 1503 and the memory core dies 1506. The IF die 1503 may be coupled to the interposer 1505 via interconnects 1509. For example, the interconnects 1509 may be microbumps having bump pitches of less than about or less than one hundred micrometers and exposed on an outside of the IF die 1503. A portion of each of the interconnects 1509 may be coupled to the one or more power lines 1510. Another portion of each of the interconnects 1509 may be coupled to one or more of the channels 1511.

In the above descriptions, DRAM is merely one example, and the embodiments and the descriptions herein are not intended to be limited to DRAM. Memory devices other than DRAM, such as a static random-access memory (SRAM), a flash memory, an erasable programmable read-only memory (EPROM), a magnetoresistive random-access memory (MRAM), and a phase-change memory, can also be applied as the apparatuses of the present embodiments. Furthermore, devices other than memory, including logic ICs, such as a microprocessor and an application-specific integrated circuit (ASIC), are also applicable as the apparatuses according to the present embodiments.

Although various embodiments of the disclosure have been described in detail, it will be understood by those skilled in the art that embodiments of the disclosure may extend beyond the specifically described embodiments to other alternative embodiments and/or uses and modifications and equivalents thereof. In addition, other modifications which are within the scope of the disclosure will be readily apparent to those of skill in the art based on the described embodiments. It is also contemplated that various combination or sub-combination of the specific features and aspects of the embodiments may be made and still falling within the scope of the disclosure. It should be understood that various features and aspects of the embodiments can be combined with or substituted for one another in order to form varying mode of the embodiments. Thus, it is intended that the scope of the disclosure should not be limited by the particular embodiments described above.

What is claimed is:

1. An apparatus, comprising:
a contact plug including:
a lower conductive plug coupled to an active region of a semiconductor substrate; and
an upper conductive plug on the lower conductive plug, coupled to a memory cell capacitor; and
an insulating member adjacent to the contact plug, wherein
a bottom part of the upper conductive plug is higher than a bottom part of the insulating member.

2. The apparatus according to claim 1, wherein
the lower conductive plug extends to the active region of the semiconductor substrate,
the upper conductive plug includes the bottom part thereof contacting a top part of the lower conductive plug, and
the insulating member includes the bottom part thereof extending partway into the lower conductive plug.

3. The apparatus according to claim 2, wherein the insulating member is adjacent to the lower and upper conductive plugs of the contact plug on one side and to another upper conductive plug of another contact plug on another side and is configured to isolate the lower and upper conductive plugs of the contact plug from the other upper conductive plug of the other contact plug.

4. The apparatus according to claim 3, wherein the insulating member is further adjacent to another lower conductive plug of the other contact plug on the other side and is further configured to isolate the lower and upper conductive plugs of the contact plug from the other lower and upper conductive plugs of the other contact plug.

5. The apparatus according to claim 1, wherein the insulating member is configured to prevent a short circuit between at least one of the lower conductive plug or the upper conductive plug of the contact plug and at least one of another lower conductive plug or another upper conductive plug of another contact plug.

6. The apparatus according to claim 1, wherein the insulating member includes silicon nitride.

7. The apparatus according to claim 1, wherein the lower conductive plug includes a lower part coupled to the active region of the semiconductor substrate and an upper part coupled to the upper conductive plug.

8. The apparatus according to claim 7, wherein the lower part includes polysilicon, and the upper part includes cobalt or cobalt silicide.

9. The apparatus according to claim 1, wherein the upper conductive plug includes a first metal part under the memory cell capacitor and a second metal part on bottom and side surfaces of the first metal part, the second metal part in contact with a top surface of the lower conductive plug.

10. The apparatus according to claim 9, wherein the first metal part includes tungsten, and the second metal part includes titanium or titanium nitride.

11. The apparatus according to claim 9, wherein the second metal part is located higher than the bottom part of the insulating member.

12. The apparatus according to claim 1, wherein a center of the lower conductive plug is shifted from a center of the upper conductive plug horizontally.

13. An apparatus, comprising:
a first contact plug and a second contact plug each contacting a memory cell capacitor and configured to couple the memory cell capacitor to an active region of a semiconductor substrate, the first and second contact plugs each comprising:
a lower conductive plug extending to the active region of the semiconductor substrate; and
an upper conductive plug contacting the lower conductive plug and the memory cell capacitor at lower and upper ends, respectively; and
an insulating member located between the first and second contact plugs and configured to isolate the first and second contact plugs from each other, wherein
a bottom part of the upper conductive plug is positioned higher than a bottom part of the insulating member above the semiconductor substrate.

14. The apparatus according to claim 13, wherein
the insulating member is adjacent to the lower and upper conductive plugs and extends partway into the lower conductive plug, and
a top part of the upper conductive plug is positioned at a same height as a top part of the insulating member above the semiconductor substrate.

15. The apparatus according to claim 13, wherein
the lower conductive plug includes a lower part including polysilicon and an upper part including cobalt or cobalt silicide, and
the upper conductive plug includes a metal part contacting the upper part of the lower conductive plug.

16. The apparatus according to claim 13, wherein the insulating member includes silicon nitride.

17. An apparatus, comprising:
a plurality of memory cell capacitors;
a plurality of contact plugs provided between the memory cell capacitors and a semiconductor substrate; and
a plurality of insulating members, each provided between neighboring contact plugs among the plurality of contact plugs, wherein
the contact plugs each include a lower conductive part extending to the semiconductor substrate and an upper conductive part on the lower conductive part, the lower and upper conductive parts together configured to couple an associated memory cell capacitor to a corresponding source/drain region of the semiconductor substrate, and
the upper conductive part has a bottom height greater than a bottom height of the insulating member above the semiconductor substrate.

18. The apparatus according to claim 17, wherein the upper conductive part of the contact plug is directly coupled to, at top and bottom ends thereof, a lower electrode pillar of the memory cell capacitor and the lower conductive part of the contact plug, respectively.

19. The apparatus according to claim 17, further comprising a plurality of bit lines, wherein each of the insulating members is provided between neighboring bit lines among the plurality of bit lines.

20. The apparatus according to claim 19, wherein
the lower conductive part of the contact plug extends between the neighboring bit lines and to the source/drain region of the semiconductor substrate,
the insulating member extends partway into the lower conductive part of the contact plug, and
a top surface of the upper conductive part of the contact plug is positioned at a same height as a top surface of the insulating member above the semiconductor substrate.
